(19) United States
(12) Patent Application Publication
(10) Pub. No.: US 2022/0363833 A1
(43) Pub. Date: Nov. 17, 2022

(54) LIQUID COMPOSITION, METALLIC LUSTER FILM, AND ARTICLE

(71) Applicants: FUJIFILM Business Innovation Corp., Tokyo (JP); NATIONAL UNIVERSITY CORPORATION CHIBA UNIVERSITY, Chiba-shi (JP)

(72) Inventors: Satoya SUGIURA, Kanagawa (JP); Wataru YAMADA, Kanagawa (JP); Katsuyoshi HOSHINO, Chiba (JP); Satoru TSUKADA, Chiba (JP); Rihito TAMURA, Chiba (JP); Hirotaka DOI, Chiba (JP)

(73) Assignees: FUJIFILM Business Innovation Corp., Tokyo (JP); NATIONAL UNIVERSITY CORPORATION CHIBA UNIVERSITY, Chiba-shi (JP)

(21) Appl. No.: 17/724,602

(22) Filed: Apr. 20, 2022

(30) Foreign Application Priority Data
May 11, 2021 (JP) 2021-080265

(51) Int. Cl. C08G 75/06; C08J 3/11

(52) U.S. Cl. CPC C08G 75/06; C08J 3/11

(57) ABSTRACT

A liquid composition contains a thiophene polymer and a solvent, and the difference |δp₂−δp₁| is 7.7 MPa^{0.5} or more and 13.4 MPa^{0.5} or less between a dipole-dipole force term δp₁ of Hansen solubility parameter of the thiophene polymer and a dipole-dipole force term δp₂ of Hansen solubility parameter of the solvent.

### CROSS-REFERENCE TO RELATED APPLICATIONS

This application is based on and claims priority under 35 USC 119 from Japanese Patent Application No. 2021-080265 filed May 11, 2021.

### BACKGROUND

### (i) Technical Field

The present disclosure relates to a liquid composition, a metallic luster film, and an article.

### (ii) Related Art

Japanese Unexamined Patent Application Publication No. 2017-052856 discloses a method for producing a metallic luster film composed of a thiophene polymer by electrolytically polymerizing a thiophene monomer on a conductive material using a potential sweep method,

Japanese Unexamined Patent Application Publication No. 2017-110232 discloses a film having metallic luster and containing a thiophene polymer having a weight-average molecular weight distribution peak within a range of 200 or more and 30000 or less.

Japanese Unexamined Patent Application Publication No. 2018-012831 discloses an article with metallic luster, which includes a mixture of at least any one of a polyester resin, a polycarbonate resin, a polyvinylpyrrolidone resin, a polystyrene resin, a polymethyl methacrylate resin, and a styrene-acrylic copolymer resin, and a thiophene polymer.

Japanese Patent No. 6031197 discloses a coating solution for forming a metallic-tone coating film containing polythiophene doped with chloride ions or perchlorate ions.

Japanese Patent No. 6308624 discloses a film with a gold-colored luster or copper-colored luster, which contains a thiophene polymer doped with at least one of perchlorate ions, hexafluorophosphate ions, tetrafluoroborate ions, chloride ions, and paratoluenesulfonate ions and produced by polymerizing at least one of alkoxythiophene and alkylthiophene each having 1 or 2 carbon atoms so that the weight-average molecular weight distribution peak is within a range of 200 or more and 30000 or less.

### SUMMARY

A liquid composition containing a thiophene polymer may be thickened with time, and a film formed by applying the thickened liquid composition may not have metallic luster feel depending on the viewing angle.

Aspects of non-limiting embodiments of the present disclosure relate to a liquid composition which forms a metallic luster film and which has excellent viscosity stability with time.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a liquid composition containing a thiophene polymer and a solvent, and the difference |δp₂−δp₁| is 7.7 MPa^{0.5} or more and 13.4 MPa^{0.5} or less between the dipole-dipole force term δp₁ of Hansen solubility parameter of the thiophene polymer and the dipole-dipole force term δp₂ of Hansen solubility parameter of the solvent.

### DETAILED DESCRIPTION

An exemplary embodiment of the present disclosure is described below. The description and examples are illustrative of the exemplary embodiment, and do not limit the scope of the exemplary embodiment.

In the present disclosure, the upper limit value or lower limit value described in one of the numerical ranges stepwisely described may be substituted by the upper limit value or lower limit value of another of the numerical ranges stepwisely described. In addition, the upper limit value or lower limit value of a numerical range described in the present disclosure may be substituted by the value described in an example.

In the present disclosure, each of the components may contain plural corresponding materials. In the present disclosure, when plural materials corresponding to each of the components are present in a composition, the mention of the amount of each of the components in the composition represents the total amount of the plural materials present in the composition unless otherwise specified.

### <Liquid Composition>

A liquid composition according to an exemplary embodiment of the disclosure contains a thiophene polymer and a solvent, and the difference δp₂−δp₁| (unit: MPa^{0.5}) is 7.7 or more and 13.4 or less between the dipole-dipole force term δp₁ of Hansen solubility parameter of the thiophene polymer and the dipole-dipole force term δp₂ of Hansen solubility parameter of the solvent.

In the present disclosure, the inventor found that when the liquid composition has the relation described above between the Hansen solubility parameters of the thiophene polymer and the solvent constituting the composition, the liquid composition has excellent viscosity stability with time.

Although not bound to a particular theory, it is supposed that when the difference |δp₂−δp₁| (unit: MPa^{0.5}) is less than 7.7 between δp₁ of the thiophene polymer and δp₂ of the solvent, an increase in viscosity of the liquid composition occurs due to the strong interaction between the thiophene polymer and the solvent, while it is supposed that when the difference |δp₂−δp₁| (unit: MPa^{0.5}) exceeds 13.4 between δp₁ of the thiophene polymer and δp₂ of the solvent, an increase in viscosity of the liquid composition occurs due to the insolubilization of the thiophene polymer dissolved once in the solvent.

From the viewpoint described above, the difference |δₚ₂−δₚ₁| (unit: MPa^{0.5}) is 7.7 or more and 13.4 or less, preferably 10.0 or more and 13.4 or less, and more preferably 12.0 or more and 13.4 or less between δₚ₁ of the thiophene polymer and δₚ₂ of the solvent.

The liquid composition according to the exemplary embodiment of the present disclosure has excellent viscosity stability with time and hardly causes an increase in viscosity and thus can stably form a film having excellent metallic luster.

Further, the liquid composition according to the exemplary embodiment of the present disclosure has the relation described above between the Hansen solubility parameters of the thiophene polymer and solvent constituting the liquid composition, that is, the difference |δp₂−δp₁| (unit: MPa^{0.5}) is 7.7 or more and 13.4 or less between δp₁ of the thiophene polymer and δp₂ of the solvent. It is thus supposed that when a film of the thiophene polymer is formed by evaporating the solvent from a coating film, the thiophene polymer is aligned in layers, thereby easily exhibiting metallic luster.

The Hansen solubility parameter (HSP) is described below.

HSP includes the three components, dispersion force term δd, dipole-dipole force term δp, and hydrogen bonding force term δh. The units of all three components are MPa^{0.5}.

In the exemplary embodiment of the present disclosure, HSP is a value at a temperature of 25° C. (298.15 K). The values described in “Hansen Solubility Parameters: A User's handbook, Second Edition” are used as HSP. The values of chemical substances not described are calculated by using a software “Hansen Solubility Parameter in Practice (HSPiP) Ver 5. 202”.

In the exemplary embodiment of the present disclosure, the HSP of a mixed solvent is a volume ratio-weighted average. For example, the HSP of a mixed solvent prepared by mixing pure solvent A (δd_{A}, Δp_{A}, δh_{A}) and pure solvent B (Δd_{B}, δp_{B}, δh_{B}) at a volume ratio of 1:1 is (0.5·δd_{A}+0.5·Δd_{B}, 0.5·δp_{A}+0.5·δp_{B}, 0.5·δh_{A}+0.5·δh_{B}).

In the exemplary embodiment of the present disclosure, when plural kinds of thiophene polymers are mixed (for example, poly(methoxythiophene) and poly(butoxythiophene) are mixed) and used, the HSP of a mixture of the thiophene polymers is a volume ratio-weighted average. For example, the HSP of a mixture prepared by mixing thiophene polymer M (δd_{M}, δp_{M}, δh_{M}) and thiophene polymer N (δd_{N}, δp_{N}, δh_{N}) at a mass ratio of 1:1 is (0.5·δd_{M}+0.5·δd_{N}, 0.5·δp_{M}+0.5·δp_{N}, 0.5·δh_{M}+0.5·δh_{N}).

When the HSP of the thiophene polymer is (δd₁, δp₁, δh₁) and the HSP of the solvent is (δd₂, δp₂, δh₂), the distance Ra between the thiophene polymer and the solvent in a HSP space is determined by the following formula.

Ra={4(δd₂−δd₁)²+(δp₂−δp₁)²+(δh₂−δh₁)²}^{0.5}

In the exemplary embodiment of the present disclosure, from the viewpoint of the excellent viscosity stability with time of the liquid composition, the distance Ra (unit: MPa^{0.5}) between the thiophene polymer and the solvent in the HSP space is preferably 9.1 or more and 14.1 or less, more preferably 12.0 or more and 14.1 or less, and still more preferably 13.0 or more and 14.1 or less.

In the exemplary embodiment of the present disclosure, the dipole-dipole force term δp₁ (unit: MPa^{0.5}) of HSP of the thiophene polymer is preferably 2.0 or more and 5.0 or less, more preferably 3.0 or more and 4.8 or less, and still more preferably 3.3 or more and 4.6 or less.

In the exemplary embodiment of the present disclosure, the dipole-dipole force term δp₂ (unit: MPa^{0.5}) of HSP of the solvent is preferably 8.0 or more and 20.0 or less, more preferably 10.0 or more and 20.0 or less, and still more preferably 12.0 or more and 18.0 or less.

In the exemplary embodiment of the present disclosure, the dispersion force term δd₁ and hydrogen bonding force term δh₁ of HSP of the thiophene polymer and the dispersion force term δd₂ and hydrogen bonding force term δh₂ of HSP of the solvent are not limited. However, (δd₁, δp₁, δh₁) and (δd₂, δp₂, δh₂) are preferably such that the distance Ra between the thiophene polymer and the solvent in the HSP space is within the range described above.

The components of the liquid composition according to the exemplary embodiment are described in detail below.

### [Thiophene Polymer]

The thiophene polymer is a polymer formed by polymerization of two or more thiophenes. A film containing the thiophene polymer exhibits metallic luster due to reflection of light at a specific wavelength from the thiophene polymer aligned in layers.

The thiophene polymer may be a polymer formed by polymerization of one type of thiophene or a polymer formed by polymerization of plural types of thiophenes. An example of the thiophene polymer according to the exemplary embodiment is a polymer represented by the following general formula.

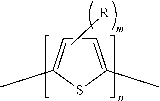

In the general formula, R is a substituent, m is an integer of 1 or 2, and n is an integer of 2 or more. One or plural substituents may be present as R. When m is 2, two Rs possessed by one thiophene ring may be the same or different. When m is 2, two Rs in one thiophene ring may be linked together to form a cyclic group.

For example, R represents an alkoxy group, an alkyl group, an amino group, a hydroxyl group, a hydroxyalkyl group, an aryl group, an allyl group, a cyano group, or a halogeno group. From the viewpoint that a film containing a thiophene polymer more securely exhibits metallic luster, R is preferably an alkoxy group, an alkyl group, an amino group, or a hydroxyl group, more preferably an alkoxy group, an alkyl group, or an amino group, and still more preferably an alkoxy group or an alkyl group.

When R is an alkoxy group, from the viewpoint of the ease of alignment in layers of the thiophene polymer, the number of carbon atoms of the alkoxy group is preferably 1 or more and 8 or less, more preferably 1 or more and 6 or less, still more preferably 1 or more and 4 or less, and particularly preferably 1 or 2.

Examples of thiophenes having at least one alkoxy group include 3-methoxythiophene, 3,4-dimethoxythiophene, 3-ethoxythiophene, 3,4-diethoxythiophene, 3-propoxythiophene, 3-butoxythiophene, 3,4-ethylenedioxythiophene, 3,4-propylenedioxythiophene, and the like.

When R is an alkyl group, from the viewpoint of the ease of alignment in layers of the thiophene polymer, the number of carbon atoms of the alkyl group is preferably 1 or more and 12 or less, more preferably 1 or more and 8 or less, still more preferably 1 or more and 6 or less, even still more preferably 1 or more and 4 or less, and particularly preferably 1 or 2.

Examples of thiophenes having at least one alkyl group include 3-methylthiophene, 3,4-dimethylthiophene, 3-ethylthiophene, 3,4-diethylthiophene, 3-butylthiophene, 3-hexylthiophene, 3-heptylthiophene, 3-octylthiophene, 3-nonylthiophene, 3-decylthiophene, 3-undecylthiophene, 3-dodecylthiophene, 3-bromo-4-methylthiophene, and the like.

When R is an amino group, the amino group may be a primary amino group (—NH₂), a secondary amino group (—NHR¹, R¹ is an alkyl group or an aryl group, preferably an alkyl group), or a tertiary amino group (—NR¹R², R¹ and R² are each independently an alkyl group or an aryl group, preferably an alkyl group). From the viewpoint of the ease of alignment in layers of the thiophene polymer, the number of carbon atoms of the alkyl group in the secondary amino group or tertiary amino group is preferably 1 or 2.

Examples of a thiophene having at least one amino group include 3-aminothiophene, 3,4-diaminothiophene, 3-methylaminothiophene, 3-dimethylaminothiophene, and the like.

From the viewpoint that a film containing the thiophene polymer more securely exhibits metallic luster, the thiophene polymer is preferably a polymer produced by polymerization of at least one selected from the group including alkoxythiophene, alkylthiophene, aminothiophene, and hydroxythiophene, more preferably a polymer produced by polymerization of at least one selected from the group including alkoxythiophene and alkylthiophene, and still more preferably poly(alkoxythiophene) produced by polymerization of only alkoxythiophene, poly(alkylthiophene) produced by polymerization of only alkylthiophene, or poly(alkylthiophene) (alkoxythiophene) produced by polymerization of only alkylthiophene and alkoxythiophene. The number of carbon atoms of the alkoxy group in alkoxythiophene is preferably 1 or more and 8 or less, more preferably 1 or more and 6 or less, still more preferably 1 or more and 4 or less, and particularly preferably 1 or 2. The number of carbon atoms of the alkyl group in alkylthiophene is preferably 1 or more and 12 or less, more preferably 1 or more and 8 or less, still more preferably 1 or more and 6 or less, even still more preferably 1 or more and 4 or less, and particularly preferably 1 or 2.

From the viewpoint that the thiophene polymer is easily aligned in layers and easily exhibits metallic luster, the weight-average molecular weight of the thiophene polymer is preferably 200 or more and 30,000 or less, more preferably 500 or more and 20,000 or less, and still more preferably 1,000 or more and 10,000 or less.

The molecular weight of the thiophene polymer is measured by gel permeation chromatography (GPC). In the measurement, HPLC 1100 manufactured by Tosoh Corporation is used as a measurement apparatus, two columns of TSKgel GMHHR-M (inner diameter: 7.8 mm, length: 30 cm) manufactured by Tosoh Corporation are arranged in series and used as a column, chloroform is used as a solvent, and monodisperse polystyrene is used as a standard sample.

The mass ratio of the thiophene polymer contained in the liquid composition according to the exemplary embodiment relative to the total mass of the liquid composition is preferably 0.1% by mass or more and 20% by mass or less, more preferably 0.5% by mass or more and 15% by mass or less, and still more preferably 1% by mass or more and 10% by mass or less.

The thiophene polymer is synthesized by, for example, an oxidative polymerization method. The oxidative polymerization method is a method of polymerizing thiophene in a liquid phase or solid phase using an oxidizer.

Examples of the oxidizer include ferric salts, cupric salts, cerium salts, dichromate salts, permanganate salts, ammonium persulfate, boron trifluoride, bromate salts, hydrogen peroxide, chlorine, bromine, and iodine.

The oxidizer is preferably a ferric salt, and a ferric salt may be a hydrate.

Examples of counter ions of ferric salts include chloride ions, citrate ions, oxalate ions, paratoluenesulfonate ions, perchlorate ions, hexafluorophosphate ions, tetrafluoroborate ions, and the like. When at least one of perchlorate ion, hexafluorophosphate ion, and tetrafluoroborate ion is used as the counter ion of a ferric salt, a film having luster close to gold can be formed.

When the oxidizer having a perchlorate ion, a hexafluorophosphate ion, a tetrafluoroborate ion, or a chloride ion as a counter ion is used, the counter ion is stably bonded to the thiophene polymer and remains, and thus a metallic luster state can be stably maintained.

The oxidative polymerization is preferably performed in a solvent. The solvent is preferably a solvent which dissolves the thiophenes and the oxidizer and which causes efficient polymerization of the thiophene. The solvent is preferably an organic solvent having high polarity and some degree of volatility.

Examples of the solvent used in the oxidative polymerization include acetonitrile, nitromethane, γ-butyrolactone, propylene carbonate, N-methylpyrrolidone, dimethylformamide, dimethylsulfoxide, 1-methyl-2-pyrrolidinone, 2-butanone, tetrahydrofuran, acetone, methanol, anisole, chloroform, ethyl acetate, hexane, trichloroethylene, cyclohexanone, dichloromethane, ethanol, butanol, pyridine, dioxane, and a mixture thereof.

From the viewpoint of solubility of the thiophene polymer, the solvent used in the oxidative polymerization is preferably an aprotic polar solvent and more preferably at least one selected from the group including acetonitrile, nitromethane, γ-butyrolactone, propylene carbonate, N-methylpyrrolidone, dimethylformamide, and dimethylsulfoxide.

In the oxidative polymerization, the mass ratio of the solvent to thiophene is preferably solvent:thiophene=1:0.00007 to 1:7 and more preferably 1:0.0007 to 1:0.7.

In the oxidative polymerization, for example, when the oxidizer is iron(III) perchlorate n-hydrate [reagent grade], the mass ratio of the solvent to oxidizer is preferably solvent:iron(III) perchlorate n-hydrate [reagent grade]=1:0.0006 to 1:6 and more preferably 1:0.006 to 1:0.6.

In the oxidative polymerization, the mass ratio of the thiophene to oxidizer is preferably thiophene:oxidizer=1:0.1 to 1:1000 and more preferably 1:1 to 1:100.

The oxidative polymerization method and operation are not particularly limited. The oxidative polymerization may be performed by adding and dissolving the thiophene and the oxidizer at a time in a solvent, or the oxidative polymerization may be performed by separately preparing a solution by dissolving the thiophene in a solvent and a solution by dissolving the oxidizer in a solvent and then mixing both solutions.

The molecular weight of the thiophene polymer can be adjusted by changing the thiophene concentration, the reaction temperature, and the reaction time of the oxidative polymerization.

The thiophene polymer synthesized by the oxidative polymerization method may be used directly as a solution or used as a powdery thiophene polymer after removal of the solvent.

The powdery thiophene polymer may contain impurities derived from the oxidizer used for oxidative polymerization. For the purpose of removing the impurities, at least one of treatments (a), (b), and (C) described below may be performed.

(a) The thiophene polymer is washed with a poor solvent.
(b) A solution prepared by dissolving the thiophene polymer in a good solvent is dropped in a poor solvent to precipitate the thiophene polymer.
(c) A poor solvent is dropped in a solution prepared by dissolving the thiophene polymer in a good solvent to precipitate the thiophene polymer.

The poor solvent is an alcohol such as preferably methanol, ethanol, isopropanol, or the like, and the good solvent is preferably dimethylformamide, dimethylsulfoxide, tetrahydrofuran, or the like.

The method for synthesizing the thiophene polymer may be an electrolytic polymerization method. The thiophene polymer produced by the electrolytic polymerization method can be dissolved in a solvent and used in an exemplary embodiment of the disclosure.

The electrolytic polymerization method represents a method in which a monomer is electro-oxidized in an electrolytic solution, prepared by dissolving the monomer in a solvent containing a supporting electrolyte, thereby forming a film composed of an insoluble polymer on a conductive material.

The solvent used in electrolytic polymerization is, for example, water, an alcohol, or a mixed solvent thereof. Also, the solvent described in “Electrochemical Measurement Methods First volume” pp. 107-114 (Akira Fujishima, Masuo Aizawa, Toru Inoue, Gihodo-Shuppan, 1984) may be used.

The supporting electrolyte is preferably an electrolyte which is sufficiently dissolved in a solvent and is hardly electrolyzed. When focusing on cation, the supporting electrolyte is preferably a lithium salt, a sodium salt, a potassium salt, a calcium salt, or a tetraalkylammonium salt, while when focusing on anion, the supporting electrolyte is preferably a halide, a sulfate salt, a nitrate salt, a phosphate salt, a perchlorate salt, a boron trifluoride salt, or a hexafluorophosphate salt.

The concentration of thiophene in the electrolytic solution is preferably 0.1 mmol/L or more and solubility or less and more preferably 1 mmol/L or more and 1 mol/L or less.

The concentration of the supporting electrolyte in the electrolytic solution is preferably 0.001 mol/L or more and solubility or less and more preferably 0.01 mol/L or more and 1 mol/L or less.

The electrolytic polymerization method is preferably a three-electrode type using s conductive material functioned as a working electrode, a counter electrode, and a reference electrode serving as a reference potential, or a two-electrode type using a conductive material functioned as a working electrode and a counter electrode. The three-electrode type is preferred from the viewpoint that the desired thiophene polymer can be polymerized with high reproducibility.

In any one of the three-electrode type and the two-electrode type, the material of the conductor functioned as the working electrode is preferably a material which is stable against electro-oxidation. For example, an electrode (a transparent glass electrode, a metal electrode, a glassy carbon electrode, or the like) coated with a conductive film of indium tin oxide, tin oxide, or the like is preferred. The counter electrode is preferably the electrode described above, or a metal electrode of stainless, a copper plate, or the like. The reference electrode is preferably an Ag/AgCl electrode or a saturated calomel electrode.

In the electrolytic polymerization method, anodic oxidation is performed by using a potential sweep method. The potential sweep method represents a treatment of applying a potential while changing the potential at a constant rate.

In the potential sweep method, the potential is preferably swept between a negative potential and a positive potential. In this case, the negative potential is preferably within a range of −1.5 V or more and −0.01 V or less, more preferably within a range of −1.0 V or more and −0.1 V or less, and still more preferably within a range of −0.7 V or more and −0.2 V or less. The positive potential is preferably within a range of +1.0 V or more and +3.0 V or less, more preferably within a range of +1.0 V or more and +2.0 V or less, and still more preferably within a range of +1.0 V or more and +1.5 V or less.

The sweep rate of the potential sweep method is preferably within a range of 0.1 mV/second or more and 10 V/second or less, more preferably within a range of 1 mV/second or more and 1 V/second or less, and still more preferably within a range of 2 mV/second or more and 300 mV/second or less,

The time of electrolytic polymerization is preferably within a range of 1 second or more and 5 hours or less, and more preferably within a range of 10 seconds or more and 1 hour or less.

The electrolysis temperature during electrolytic polymerization is preferably within a range of −20° C. or more 60° C. or less.

During the electrolytic polymerization, electrolysis is reaction in which the component materials in the atmosphere are little involved and is performed at a relatively low potential and thus can be performed in the atmosphere. From the viewpoint of avoiding the possibility of contamination of the formed film with oxidation of impurities in the electrolytic solution, electrolysis is preferably performed in a nitrogen gas or argon gas atmosphere, but there is little concern of contamination. But still, the presence of a large amount of oxygen in the electrolytic solution may influence the electrode reaction, and thus bubbling with inert gas (nitrogen gas or argon gas) is also useful.

### [Solvent]

The liquid composition according to the exemplary embodiment of the disclosure contains a solvent. The solvent constituting the liquid composition is preferably evaporated in the process of forming a metallic luster film and substantially does not remain in the metallic luster film.

From the viewpoint of solubility of the thiophene polymer, the solvent is preferably an aprotic polar solvent. From the viewpoint of excellent viscosity stability with time of the liquid composition, the solvent is preferably propylene carbonate, N-methylpyrrolidone, dimethylformamide, dimethylsulfoxide, or a mixed solvent thereof, and is more preferably propylene carbonate.

When used for forming a metallic luster film, the liquid composition according to the exemplary embodiment of the disclosure preferably has a viscosity of 1 mPa·s or more and 100 mPa·s or less and more preferably 10 mPa·s or more and 50 mPa·s or less.

The viscosity of the liquid composition according to the exemplary embodiment of the disclosure is measured by using a rotational viscometer under the conditions including a sample temperature of 22° C.±0.5° C. and a shear rate of 10 s⁻¹.

### [Other Components]

The liquid composition according to the exemplary embodiment of the disclosure may contain various additives. Examples of the additives include a thermal stabilizer, an antioxidant, an antireductant, a defoaming agent, a penetrant, a leveling agent, a surfactant, a dispersion stabilizer, a viscosity modifier, a pH adjuster, an ultraviolet absorber, an antiseptic agent, an anti-mold agent, and the like.

### <Metallic Luster Film>

A metallic luster film according to an exemplary embodiment of the disclosure is a film formed by drying the liquid composition according to the exemplary embodiment.

The metallic luster film according to the exemplary embodiment can be formed by, for example, applying the liquid composition according to the exemplary embodiment on an article to form a coating film and then drying the coating film.

Examples of a method for forming a coating film include a drop casting method, a spin coating method, a bar coating method, a dip coating method, a screen printing method, an offset printing method, an ink jet method, or the like.

In order to dry the coating film, drying treatment (for example, heating or air blowing) may be performed, or natural drying may be performed.

From the viewpoint of fixing the metallic luster film on the article after forming the metallic luster film, the metallic luster film is preferably pressurized. The pressurization includes rubbing.

The thickness of the metallic luster film is preferably a thickness with which metallic luster is exhibited, and specifically preferably 0.01 μm or more and 200 μm or less.

The weight-average molecular weight of the thiophene polymer contained in the metallic luster film is preferably 200 or more and 30000 or less, more preferably 500 or more and 20000 or less, and still more preferably 1000 or more and 10000 or less.

The molecular weight of the thiophene polymer contained in the metallic luster film is measured by, for example, dissolving the metallic luster film in a solvent and then extracting the thiophene polymer.

### <Article>

An article according to an exemplary embodiment of the disclosure has the metallic luster film according to the exemplary embodiment.

The article according to the exemplary embodiment of the disclosure is produced by forming the metallic luster film on an article. Examples of an object article on which the metallic luster film is formed include furniture, building members, toys, miscellaneous goods, clothing, paper products, packages, and the like. However, these are illustrative, and the article is not particularly limited as long as the metallic luster film can be formed. From the viewpoint of easy formation of the metallic luster film, the material of the article is preferably a resin, glass, paper, or the like.

### EXAMPLES

The exemplary embodiment of the disclosure is described in further detail below by exemplifying examples, but the exemplary embodiment is not limited to the examples. In addition, “parts” and “%” are on mass basis unless otherwise specified. Synthesis, treatment, production etc. are performed at room temperature (25° C.±3° C.) unless otherwise specified.

### <Synthesis of Thiophene Polymer>

### Poly(3-methoxythiophene)

In a three-neck flask, 11.4 g of 3-methoxythiophene is added, and 0.5 L of acetonitrile is added to dissolve 3-methoxythiophene in acetonitrile. Next, the inside of the three-neck flask is substituted with nitrogen and cooled to 0° C. Next, a solution prepared by dissolving 101 g of iron(III) perchlorate n-hydrate [reagent grade] in 0.5 L of acetonitrile is added dropwise while the solution and the inside of the reaction system are maintained at 5° C. or less. Next, the temperature is increased to room temperature, and then the resultant mixture is stirred at room temperature for 15 hours. Next, 1 L of methanol is added and stirred for 1 hour. Next, a solid content is collected by solid-liquid separation using a centrifugal separator and then dried under reduced pressure at 60° C. for 16 hours, producing 10.5 g of thiophene polymer.

In a beaker, 2.0 g of the synthesized thiophene polymer is placed, and 50 mL of methanol is added. Then, the liquid temperature is adjusted to 45° C., followed by stirring for 1 hour. Next, a solid content obtained by solid-liquid separation using a centrifugal separator is placed in a beaker, and 50 mL of methanol is added. Then, the liquid temperature is adjusted to 45° C., followed by stirring for 1 hour. Next, a solid content is collected by solid-liquid separation using a centrifugal separator and then dried under reduced pressure at 60° C. for 16 hours, producing 1.8 g of thiophene polymer. The weight-average molecular weight of the thiophene polymer after methanol washing is 3000.

The synthesis described above is repeated to obtain a necessary amount of poly(3-methoxythiophene). The poly(3-methoxythiophene) after methanol washing is used in examples and comparative examples described later.

### Poly(3-butoxythiophene)

In a three-neck flask, 3.1 g of 3-butoxythiophene is added, and 0.1 L of acetonitrile is added to dissolve 3-butoxythiophene in acetonitrile. Next, the inside of the three-neck flask is substituted with nitrogen and cooled to 0° C. Next, a solution prepared by dissolving 20 g of iron(III) perchlorate n-hydrate [reagent grade] in 0.1 L of acetonitrile is added dropwise while the solution and the inside of the reaction system are maintained at 5° C. or less. Next, the temperature is increased to room temperature, and then the resultant mixture is stirred at room temperature for 15 hours. Next, 0.2 L of methanol is added and stirred for 1 hour. Next, a solid content is collected by solid-liquid separation using a centrifugal separator.

The collected solid content is dissolved in 100 mL of dimethylformamide. Then, 1 L of isopropyl alcohol is added dropwise over 30 minutes while the resultant solution is stirred, thereby gradually precipitating a solid. Next, a solid content collected by solid-liquid separation using a centrifugal separator is placed in a beaker, and 50 mL of methanol is added and stirred for 1 hour after the liquid temperature is adjusted to 45° C. Next, a solid content is collected by solid-liquid separation using a centrifugal separator and then dried under reduced pressure at 60° C. for 16 hours, producing 1.9 g of thiophene polymer. The weight-average molecular weight of the thiophene polymer after methanol washing is 3200.

The synthesis described above is repeated to obtain a necessary amount of poly(3-butoxythiophene). The poly(3-butoxythiophene) after methanol washing is used in examples described later.

### Poly(3-methylthiophene) (3-methoxythiophene)

In a three-neck flask, 0.02 g of 3-methylthiophene and 2.05 g of 3-methoxythiophene are added, and 0.1 L of acetonitrile is added to dissolve the thiophenes in acetonitrile. Next, the inside of the three-neck flask is substituted with nitrogen and cooled to 0° C. Next, a solution prepared by dissolving 20 g of iron(III) perchlorate n-hydrate [reagent grade] in 0.1 L of acetonitrile is added dropwise while the solution and the inside of the reaction system are maintained at 5° C. or less. Next, the temperature is increased to room temperature, and then the resultant mixture is stirred at room temperature for 15 hours. Next, 0.2 L of methanol is added and stirred for 1 hour. Next, a solid content is collected by solid-liquid separation using a centrifugal separator.

The collected solid content is dissolved in 100 mL of dimethylformamide. Then, 1 L of isopropyl alcohol is added dropwise over 30 minutes while the resultant solution is stirred, thereby gradually precipitating a solid. Next, a solid content collected by solid-liquid separation using a centrifugal separator is placed in a beaker, and 50 mL of methanol is added and stirred for 1 hour after the liquid temperature is adjusted to 45° C. Next, a solid content is collected by solid-liquid separation using a centrifugal separator and then dried under reduced pressure at 60° C. for 16 hours, producing 1.9 g of thiophene polymer. The weight-average molecular weight of the thiophene polymer after methanol washing is 3300.

The synthesis described above is repeated to obtain a necessary amount of poly(3-methylthiophene) (3-methoxythiophene). The poly(3-methylthiophene) (3-methocythiophene) after methanol washing is used in examples described later.

### Example 1-1

First, 1 part by mass of poly(3-methoxythiophene) is dissolved in 99 parts by mass of propylene carbonate, stirred for 30 minutes by using a stirrer, and then allowed to stand for 12 hours, producing a liquid composition.

The resultant liquid composition is allowed to stand at a temperature of 24° C. for 24 hours. The viscosity of the liquid composition is measured before and after being allowed to stand at 24° C. for 24 hours, and a difference therebetween is calculated. The difference is shown in the column “Viscosity change” in Table 1. The viscosity is measured by using HAAKE precision rotational viscometer VT550 at a sample temperature of 22° C.±0.5° C. and a shear rate of 10 s⁻¹.

The liquid composition after being allowed to stand at 24° C. for 24 hours is used for forming a metallic luster film. The liquid composition is dropped and cast on a washed glass substrate and dried at a temperature of 80° C. for 40 minutes to form a metallic luster film. The thickness of the metallic luster film is about 1.0 μm.

The luster of the metallic luster film is visually observed and classified as described below. The results are shown in the column “Luster feel” in Table 1.

A: The film has a luster feel over the entire region regardless of the viewing angle.
B: The film has a luster feel depending on the viewing angle.
C: The film has no luster feel.

### Example 1-2

A liquid composition is obtained by the same method as in Example 1-1 except that the solvent is changed to dimethylsulfoxide (DMSO). In addition, a metallic luster film is formed by the same method as in Example 1-1 except that the drying temperature is changed to 25° C. Further, the viscosity change and the luster of the metallic luster film are evaluated by the same method as in Example 1-1.

### Example 1-3

A liquid composition is obtained by the same method as in Example 1-1 except that the solvent is changed to N-methylpyrrolidone (M4P). In addition, a metallic luster film is formed by the same method as in Example 1-1. Further, the viscosity change and the luster of the metallic luster film are evaluated by the same method as in Example 1-1.

### Comparative Example 1-1

A liquid composition is obtained by the same method as in Example 1-1 except that the solvent is changed to nitromethane. In addition, a metallic luster film is formed by the same method as in Example 1-1 except that the drying temperature is changed to 25° C. Further, the viscosity change and the luster of the metallic luster film are evaluated by the same method as in Example 1-1.

### Comparative Example 1-2

A liquid composition is obtained by the same method as in Example 1-1 except that the solvent is changed to acetonitrile. In addition, a metallic luster film is formed by the same method as in Example 1-1 except that the drying temperature is changed to 25° C. Further, the viscosity change and the luster of the metallic luster film are evaluated by the same method as in Example 1-1.

### Comparative Example 1-3

A liquid composition is obtained by the same method as in Example 1-1 except that the solvent is changed to acetone. In addition, a metallic luster film is formed by the same method as in Example 1-1 except that the drying temperature is changed to 25° C. Further, the viscosity change and the luster of the metallic luster film are evaluated by the same method as in Example 1-1.

### Comparative Example 1-4

A liquid composition is obtained by the same method as in Example 1-1 except that the solvent is changed to γ-butyrolactone. In addition, a metallic luster film is formed by the same method as in Example 1-1. Further, the viscosity change and the luster of the metallic luster film are evaluated by the same method as in Example 1-1.

### Comparative Example 1-5

A liquid composition is obtained by the same method as in Example 1-1 except that the solvent is changed to water. In addition, a metallic luster film is formed by the same method as in Example 1-1 except that the drying temperature is changed to 60° C. Further, the viscosity change and the luster of the metallic luster film are evaluated by the same method as in Example 1-1.

### Example 2-1

A liquid composition is obtained by the same method as in Example 1-2 except that the thiophene polymer is changed to poly(3-butoxythophene). In addition, a metallic luster film is formed by the same method as in Example 1-2. Further, the viscosity change and the luster of the metallic luster film are evaluated by the same method as in Example 1-1.

### Example 2-2

A liquid composition is obtained by the same method as in Example 1-3 except that the thiophene polymer is changed to poly(3-butoxythophene). In addition, a metallic luster film is formed by the same method as in Example 1-3. Further, the viscosity change and the luster of the metallic luster film are evaluated by the same method as in Example 1-1.

### Example 3-1

A liquid composition is obtained by the same method as in Example 1-1 except that the thiophene polymer is changed to poly(3-methylthophene) (3-methoxythiophene). In addition, a metallic luster film is formed by the same method as in Example 1-1. Further, the viscosity change and the luster of the metallic luster film are evaluated by the same method as in Example 1-1.

### Example 3-2

A liquid composition is obtained by the same method as in Example 1-2 except that the thiophene polymer is changed to poly(3-methylthophene) (3-methoxythiophene). In addition, a metallic luster film is formed by the same method as in Example 1-2. Further, the viscosity change and the luster of the metallic luster film are evaluated by the same method as in Example 1-1.

### Example 3-3

A liquid composition is obtained by the same method as in Example 1-3 except that the thiophene polymer is changed to poly(3-methylthophene) (3-methoxythiophene). In addition, a metallic luster film is formed by the same method as in Example 1-3. Further, the viscosity change and the luster of the metallic luster film are evaluated by the same method as in Example 1-1.

TABLE 1

| | | | | | | | | | | | | Metallic |
|---|---|---|---|---|---|---|---|---|---|---|---|---|
| | | | | | | | | | Liquid composition | | | luster |
| | | | | | | | | | | | Viscos- | film |
| | Thiophene polymer | | | | Solvent | | | | | | ity | Luster |
| | Type | δd₁ | δp₁ | δh₁ | Type | δd₂ | δp₂ | δh₂ | \|δp₂ − δp₁\| | Ra | change | feel |
| | — | MPa^{0.5} | MPa^{0.5} | MPa^{0.5} | — | MPa^{0.5} | MPa^{0.5} | MPa^{0.5} | MPa^{0.5} | MPa^{0.5} | mPa · s | — |
| Example 1-1 | Poly(3- | 20.4 | 4.6 | 8.4 | Propylene | 20 | 18 | 4.1 | 13.4 | 14.1 | 20 | A |
| | methoxythiophene) | | | | carbonate | | | | | | | |
| Example 1-2 | | 20.4 | 4.6 | 8.4 | DMSO | 18.4 | 16.4 | 10.2 | 11.8 | 12.59 | 15 | B |
| Example 1-3 | | 20.4 | 4.6 | 8.4 | NMP | 18 | 12.3 | 7.2 | 7.7 | 9.15 | 25 | B |
| Comparative | | 20.4 | 4.6 | 8.4 | Nitromethane | 15.8 | 18.8 | 6.1 | 14.2 | 17.1 | 40 | C |
| Example 1-1 | | | | | | | | | | | | |
| Comparative | | 20.4 | 4.6 | 8.4 | Acetonitrile | 15.3 | 18.1 | 6.1 | 13.5 | 17.1 | 35 | C |
| Example 1-2 | | | | | | | | | | | | |
| Comparative | | 20.4 | 4.6 | 8.4 | Acetone | 15.5 | 10.4 | 7 | 5.8 | 11.47 | 150 | C |
| Example 1-3 | | | | | | | | | | | | |
| Comparative | | 20.4 | 4.6 | 8.4 | γ- | 18 | 10.6 | 7.4 | 6.0 | 7.75 | 100 | C |
| Example 1-4 | | | | | Butyrolactone | | | | | | | |
| Comparative | | 20.4 | 4.6 | 8.4 | Water | 15.5 | 11 | 42.3 | 6.4 | 35.86 | 150 | C |
| Example 1-5 | | | | | | | | | | | | |
| Example 2-1 | Poly(3- | 18.7 | 3.3 | 5.7 | DMSO | 18.4 | 16.4 | 10.2 | 13.1 | 13.86 | 10 | B |
| Example 2-2 | butoxythiophene) | 18.7 | 3.3 | 5.7 | NMP | 18 | 12.3 | 7.2 | 9.0 | 9.23 | 10 | B |
| Example 3-1 | Poly(3- | 20.4 | 4.6 | 8.4 | Propylene | 20 | 18 | 4.1 | 13.4 | 14.1 | 20 | A |
| | methylthiophene)(3- | | | | carbonate | | | | | | | |
| Example 3-2 | methoxythiophene) | 20.4 | 4.6 | 8.4 | DMSO | 18.4 | 16.4 | 10.2 | 11.8 | 12.59 | 15 | B |
| Example 3-3 | | 20.4 | 4.6 | 8.4 | NMP | 18 | 12.3 | 7.2 | 7.7 | 9.15 | 25 | B |

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners skilled in the art. The embodiments were chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

What is claimed is:

1. A liquid composition comprising:
a thiophene polymer; and
a solvent,
wherein the difference |δp₂−δp₁| is 7.7 MPa^{0.5} or more and 13.4 MPa^{0.5} or less between a dipole-dipole force term δp₁ of Hansen solubility parameter of the thiophene polymer and a dipole-dipole force term δp₂ of Hansen solubility parameter of the solvent.

2. The liquid composition according to claim 1, wherein the difference |δp₂−δp₁| is 12.0 MPa^{0.5} or more and 13.4 MPa^{0.5} or less.

3. The liquid composition according to claim 1, wherein a distance Ra between the thiophene polymer and the solvent in the Hansen solubility parameter space is 9.1 MPa^{0.5} or more and 14.1 MPa^{0.5} or less.

4. The liquid composition according to claim 2, wherein a distance Ra between the thiophene polymer and the solvent in the Hansen solubility parameter space is 9.1 MPa^{0.5} or more and 14.1 MPa^{0.5} or less.

5. The liquid composition according to claim 3, wherein the distance Ra is 13.0 MPa^{0.5} or more and 14.1 MPa^{0.5} or less.

6. The liquid composition according to claim 4, wherein the distance Ra is 13.0 MPa^{0.5} or more and 14.1 MPa^{0.5} or less.

7. The liquid composition according to claim 1, wherein the solvent contains at least one selected from the group consisting of propylene carbonate, N-methylpyrrolidone, dimethylformamide, and dimethylsulfoxide.

8. The liquid composition according to claim 2, wherein the solvent contains at least one selected from the group consisting of propylene carbonate, N-methylpyrrolidone, dimethylformamide, and dimethylsulfoxide.

9. The liquid composition according to claim 3, wherein the solvent contains at least one selected from the group consisting of propylene carbonate, N-methylpyrrolidone, dimethylformamide, and dimethylsulfoxide.

10. The liquid composition according to claim 4, wherein the solvent contains at least one selected from the group consisting of propylene carbonate, N-methylpyrrolidone, dimethylformamide, and dimethylsulfoxide.

11. The liquid composition according to claim 5, wherein the solvent contains at least one selected from the group consisting of propylene carbonate, N-methylpyrrolidone, dimethylformamide, and dimethylsulfoxide.

12. The liquid composition according to claim 6, wherein the solvent contains at least one selected from the group consisting of propylene carbonate, N-methylpyrrolidone, dimethylformamide, and dimethylsulfoxide.

13. The liquid composition according to claim 1, wherein a mass ratio of the thiophene polymer is 1% by mass or more and 10% by mass or less.

14. The liquid composition according to claim 2, wherein a mass ratio of the thiophene polymer is 1% by mass or more and 10% by mass or less.

15. The liquid composition according to claim 3, wherein a mass ratio of the thiophene polymer is 1% by mass or more and 10% by mass or less.

16. The liquid composition according to claim 1, wherein the thiophene polymer contains a polymer produced by polymerizing at least one selected from the group consisting of alkoxythiophene, alkylthiophene, aminothiophene, and hydroxythiophene.

17. The liquid composition according to claim 16,
wherein the thiophene polymer contains a polymer produced by polymerizing at least alkoxythiophene, and
the alkoxythiophene contains alkoxythiophene having an alkoxy group with 1 or more and 8 or less carbon atoms.

18. The liquid composition according to claim 16,
wherein the thiophene polymer contains a polymer produced by polymerizing at least alkylthiophene, and
the alkylthiophene contains alkylthiophene having an alkyl group with 1 or more and 8 or less carbon atoms.

19. A metallic luster film comprising the liquid composition according to claim 1, which is dried.

20. An article comprising the metallic luster film according to claim 19.
